(19) United States
(12) Patent Application Publication
(10) Pub. No.: US 2023/0415206 A1
(43) Pub. Date: Dec. 28, 2023

(54) PROCESSING APPARATUS AND PROCESSING METHOD

(71) Applicant: DISCO CORPORATION, Tokyo (JP)

(72) Inventors: Naoko YAMAMOTO, Tokyo (JP); Yuki INOUE, Tokyo (JP)

(21) Appl. No.: 18/331,487

(22) Filed: Jun. 8, 2023

(30) Foreign Application Priority Data
Jun. 23, 2022 (JP) 2022-101178

(51) Int. Cl. B08B 3/04; B08B 3/08; B08B 1/00; B08B 1/02

(52) U.S. Cl. CPC B08B 3/041; B08B 3/08; B08B 1/006; B08B 1/02

(57) ABSTRACT

There is provided a processing apparatus which processes a workpiece. The processing apparatus includes a processing mechanism having a holding unit which holds the workpiece, and a processing unit which processes the workpiece held by the holding unit, a first cleaning mechanism having a spinner table on which the workpiece processed by the processing unit is held, and a cleaning fluid nozzle which supplies a cleaning fluid containing water to clean the workpiece held on the spinner table, and a second cleaning mechanism including a cleaning holding unit which holds the workpiece cleaned by the first cleaning mechanism, a polishing cleaning liquid supply unit which supplies a polishing cleaning liquid to the workpiece held by the cleaning holding unit, and a polishing pad which abuts on the workpiece supplied with the polishing cleaning liquid to polish the workpiece, thereby cleaning the workpiece.

### BACKGROUND OF THE INVENTION

### Field of the Invention

The present invention relates to a processing apparatus and a processing method.

### Description of the Related Art

A dicing apparatus such as a cutting apparatus or a laser processing apparatus to be used in a manufacturing process for a semiconductor device includes a spinner cleaning mechanism, and the spinner cleaning mechanism cleans a workpiece processed by cutting processing or laser processing (see, for example, Japanese Patent Laid-Open No. 2022-35059).

### SUMMARY OF THE INVENTION

In recent years, along with a higher integration of devices, hybrid bonding connecting electrodes formed on front surfaces of device wafers with each other has been adopted. In the hybrid bonding, since front surfaces of wafers are bonded to each other, a bonding defect may occur when foreign matter is adhered to the front surface of the wafer. In view of this, in the hybrid bonding, further reduction of adherence of foreign matter after dicing is demanded, compared with conventional bonding with bumps.

It is accordingly an object of the present invention to provide a processing apparatus and a processing method capable of further reducing adherence of foreign matter after dicing than before.

In accordance with an aspect of the present invention, there is provided a processing apparatus which processes a workpiece, including a processing mechanism having a holding unit which holds the workpiece, and a processing unit which processes the workpiece held by the holding unit, a first cleaning mechanism having a spinner table on which the workpiece processed by the processing unit is held, and a cleaning fluid nozzle which supplies a cleaning fluid containing water to clean the workpiece held on the spinner table, and a second cleaning mechanism including a cleaning holding unit which holds the workpiece cleaned by the first cleaning mechanism, a polishing cleaning liquid supply unit which supplies a polishing cleaning liquid to the workpiece held by the cleaning holding unit, and a polishing pad which abuts on the workpiece supplied with the polishing cleaning liquid to polish the workpiece, thereby cleaning the workpiece.

Preferably, in the processing apparatus, the processing mechanism may include at least any one of a cutting unit having a spindle on which a cutting blade is mounted, or a laser processing unit having a laser oscillator which generates a laser beam and a beam condenser which focuses the laser beam generated in the laser oscillator to the workpiece.

Preferably, in the processing apparatus, the polishing cleaning liquid supply unit of the second cleaning mechanism may have a first cleaning liquid supply path through which a first polishing cleaning liquid is supplied to the workpiece held by the cleaning holding unit, and a second polishing cleaning liquid supply path through which a second polishing cleaning liquid different from the first polishing cleaning liquid is supplied to the workpiece held by the cleaning holding unit.

In accordance with another aspect of the present invention, there is provided a processing method for a workpiece, including a processing step of holding a workpiece by a holding unit, and processing the workpiece held by the holding unit, a first cleaning step of, after the processing step is carried out, holding the workpiece by a spinner table, and supplying a cleaning fluid containing water to the workpiece to clean the workpiece, and a second cleaning step of, after the first cleaning step is carried out, supplying a polishing cleaning liquid to the workpiece and causing the polishing pad to abut on the workpiece and polish the workpiece to clean the workpiece.

The processing method may include a third cleaning step of, after the second cleaning step is carried out, supplying a second polishing cleaning liquid different from the polishing cleaning liquid to the workpiece and causing the polishing pad to polish the workpiece to clean the workpiece.

According to one aspect and another aspect of the present invention, it is possible to further reducing adherence of foreign matter after dicing than before.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a perspective view illustrating a configuration example of a processing apparatus according to a first embodiment of the present invention;

FIG. 2 is another perspective view illustrating the processing apparatus depicted in FIG. 1;

FIG. 3 is a perspective view of a first cleaning mechanism of the processing apparatus depicted in FIG. 1;

FIG. 4 is a perspective view of a second cleaning mechanism of the processing apparatus depicted in FIG. 1;

FIG. 5 is a flow chart indicating a flow of a processing method according to the first embodiment;

FIG. 6 is a schematic cross-sectional side view illustrating a processing step of the processing method indicated in FIG. 5;

FIG. 7 is a schematic cross-sectional side view illustrating a first cleaning step of the processing method indicated in FIG. 5;

FIG. 8 is a schematic cross-sectional side view illustrating a second cleaning step of the processing method indicated in FIG. 5;

FIG. 9 is a schematic cross-sectional side view illustrating a third cleaning step of the processing method indicated in FIG. 5;

FIG. 10 is a schematic cross-sectional side view illustrating a fourth cleaning step of the processing method indicated in FIG. 5; and

FIG. 11 is a schematic view illustrating a configuration of a laser processing unit as a processing unit of the processing apparatus according to a modification example of the first embodiment.

### DETAILED DESCRIPTION OF THE PREFERRED EMBODIMENT

A preferred embodiment of the present invention will now be described in detail with reference to the drawings. The present invention is not limited to this preferred embodiment. Also, the constituent elements used in this preferred embodiment may include those that can be easily assumed by persons skilled in the art or substantially the same elements as those known in the art. Moreover, the configurations described below may be suitably combined. Further, the configurations may be variously omitted, replaced, or changed without departing from the scope of the present invention.

### First Embodiment

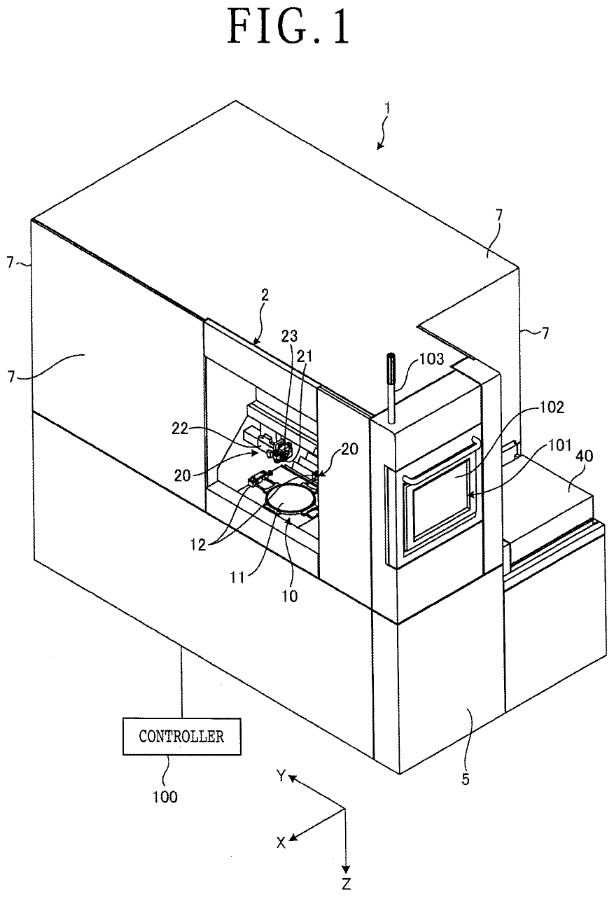

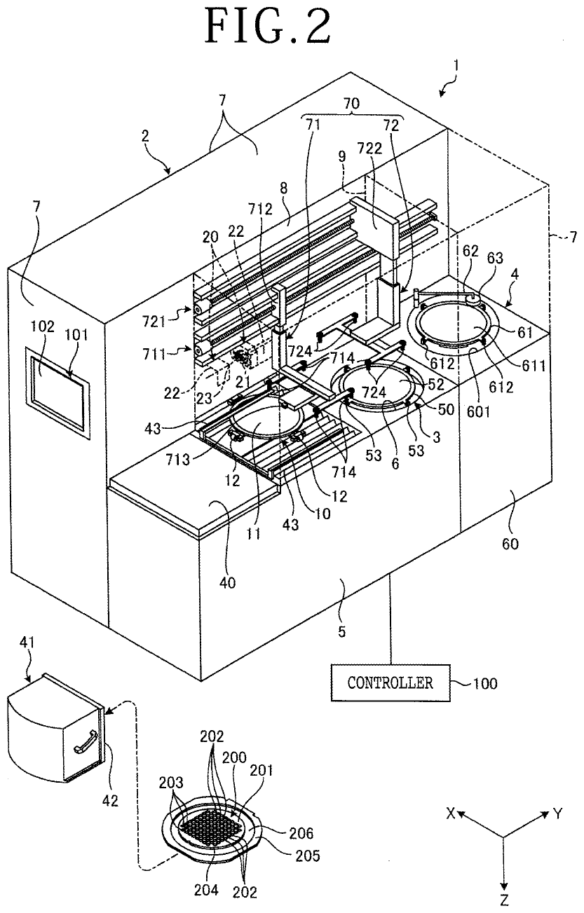

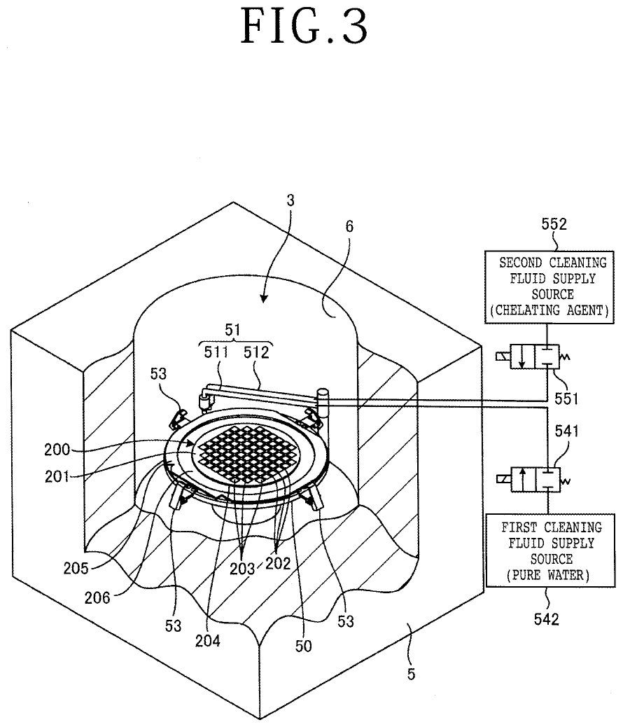

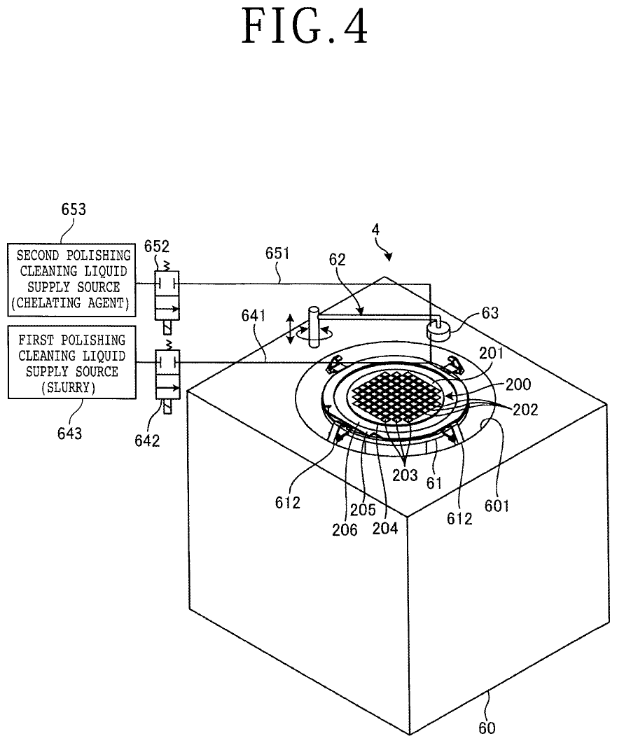

A processing apparatus 1 according to a first embodiment of the present invention will be described with reference to the attached drawings. FIG. 1 is a perspective view illustrating a configuration example of the processing apparatus 1 according to the first embodiment. FIG. 2 is another perspective view illustrating of the processing apparatus 1 depicted in FIG. 1. FIG. 3 is a perspective view of a first cleaning mechanism 3 of the processing apparatus 1 depicted in FIG. 1. FIG. 4 is a perspective view of a second cleaning mechanism 4 of the processing apparatus 1 depicted in FIG. 1.

### (Processing Apparatus)

The processing apparatus 1 according to the first embodiment is a cutting apparatus which performs cutting processing on a workpiece 200 depicted in FIG. 1. In the first embodiment, the workpiece 200 that is a processing object of the processing apparatus 1 is a wafer such as a disc-shaped semiconductor wafer formed of silicon, sapphire, or gallium arsenide, as a base material of a substrate. The workpiece 200 has a plurality of devices 203 formed in respective regions demarcated by a plurality of dividing lines 202 in a grid manner on a front surface 201 thereof.

The device 203 is, for example, an integrated circuit device such as an integrated circuit (IC) or a large scale integration (LSI), a charge coupled device (CCD), or a memory (semiconductor storage device). Also, the device 203 has unillustrated electrodes on its front surface. Each of the electrodes is flat and in the first embodiment, preferably, is positioned to be flush with the front surface of the device 203. The electrode is formed of a conductive metal such as a copper alloy, and connects the device 203 of the workpiece 200 with a device of another workpiece or a device of a device chip. Specifically, in the first embodiment, the workpiece 200 is a workpiece in which a device of another workpiece or a device of a device chip is superimposed on the device 203 and the electrodes of the device 203 are bonded to electrodes of the relevant device of another workpiece or electrodes of the relevant device of the device chip. Thus, in the first embodiment, the workpiece 200 is a workpiece obtained by what is generally called hybrid bonding.

As an alternative, the workpiece 200 may be what is generally called a TAIKO (registered trademark) wafer having a central thin portion and a peripheral thick-walled portion. Further, in addition to the wafers described above, the workpiece 200 may be a substrate such as a rectangular package substrate having a plurality of devices sealed with a resin, a ceramic substrate, a ferrite substrate, and a substrate including at least one of nickel or iron. In the first embodiment, an adhesive tape 206 having an annular frame 205 mounted on a peripheral edge thereof is attached to a back surface 204 of the workpiece 200, and the workpiece 200 is supported by the annular frame 205 through the adhesive tape 206.

The processing apparatus 1 depicted in FIG. 1 is a cutting apparatus which holds the workpiece 200 by a holding unit 10 to perform cutting processing (corresponding to processing) on the workpiece 200 with a cutting blade 21 along the dividing lines 202. The processing apparatus 1 includes a processing mechanism 2, a first cleaning mechanism 3, a second cleaning mechanism 4, a transfer mechanism 70, and a controller (control unit) 100, as depicted in FIG. 2.

As depicted in FIG. 2, the processing mechanism 2 includes a holding unit 10 which holds under suction the workpiece 200 on a holding surface 11, a cutting unit 20 which is a processing unit which performs cutting processing on the workpiece 200 held by the holding unit with the cutting blade 21, and an imaging unit which captures an image of the workpiece 200 held by the holding unit 10.

In addition, as depicted in FIG. 2, the processing mechanism 2 includes a moving unit which relatively moves the holding unit 10 and the cutting unit 20. The moving unit includes an X-axis moving unit which processing-feeds the holding unit 10 in an X-axis direction parallel to a horizontal direction, a Y-axis moving unit which indexing-feeds the cutting unit 20 in a Y-axis direction parallel to the horizontal direction and perpendicular to the X-axis direction, a Z-axis moving unit which cutting-feeds the cutting unit 20 in a Z-axis direction parallel to a vertical direction perpendicular to both the X-axis direction and the Y-axis direction, and a rotational moving unit which rotates the holding unit 10 about its axis parallel to the Z-axis direction. As depicted in FIG. 1, the processing apparatus 1 is what is generally called a facing dual type cutting apparatus as a dicer having two spindles in which the processing mechanism 2 has two cutting units 20.

The X-axis moving unit moves the holding unit 10 in the X-axis direction that is a processing-feeding direction, to thereby processing-feed the holding unit 10 and the cutting unit 20 relative to each other along the X-axis direction. The Y-axis moving unit moves the cutting unit 20 in the Y-axis direction that is an indexing-feeding direction, to thereby indexing-feed the holding unit 10 and the cutting unit 20 relative to each other along the Y-axis direction. The Z-axis moving unit moves the cutting unit 20 in the Z-axis direction that is a cutting-feeding direction, to thereby cutting-feed the holding unit 10 and the cutting unit 20 relative to each other along the Z-axis direction.

The X-axis moving unit includes a known ball screw provided rotatably about its axis, a known motor which rotates the ball screw about its axis to move the holding unit 10 in the X-axis direction, and known guide rails which movably support the holding unit 10 in the X-axis direction. Also, the Y-axis moving unit includes a known ball screw provided rotatably about its axis, a known motor which rotates the ball screw about its axis to move the cutting unit 20 in the Y-axis direction, and known guide rails which movably support the cutting unit 20 in the Y-axis direction. In addition, the Z-axis moving unit includes a known ball screw provided rotatably about its axis, a known motor which rotates the ball screw about its axis to move the cutting unit 20 in the Z-axis direction, and known guide rails which movably support the cutting unit 20 in the Z-axis direction. The rotational moving unit includes a known motor which rotates the holding unit 10 about its axis, and the like.

The holding unit 10 has a shape of a disc, and the holding surface 11 for supporting the workpiece 200 thereon is formed of a porous ceramic material or the like. Also, the holding unit 10 is provided movably in the X-axis direction in a range of a processing region below the cutting unit 20 to a loading/unloading region which is apart from the processing region below the cutting unit 20 and where the workpiece 200 is loaded/unloaded by the X-axis moving unit, and is provided movably about its axis parallel to the Z-axis direction by the rotational moving unit.

The holding unit 10 is connected to an unillustrated vacuum suction source and sucked by the vacuum suction source, to suck and hold the workpiece 200 placed on the holding surface 11. In the first embodiment, the holding unit 10 sucks and holds the back surface 204 side of the workpiece 200 through the adhesive tape 206. Moreover, as depicted in FIG. 2, a plurality of clamps 12 are provided around the holding unit 10 to clamp the annular frame 205.

The cutting unit 20 is cutting means having the cutting blade 21 detachably mounted thereon to cut the workpiece 200 held by the holding unit 10. Each of the cutting units 20 is provided to be freely movable in Y-axis direction by the Y-axis moving unit with respective to the workpiece 200 held by the holding unit 10 and provided to be freely movable in the Z-axis direction by the Z-axis moving unit with respective to the workpiece 200 held by the holding unit 10. The cutting unit 20 is able to position the cutting blade 21 at a desired position of the holding surface 11 of the holding unit 10 by the X-axis moving unit, the Y-axis moving unit, and the Z-axis moving unit.

As depicted in FIG. 2, the cutting unit 20 has the cutting blade 21, a spindle housing 22 provided to freely be movable in the Y-axis direction and the Z-axis direction by the Y-axis moving unit and the Z-axis moving unit, respectively, a spindle 23 provided in the spindle housing 22 as a rotational axis to be rotatable about its axis, and an unillustrated spindle motor which causes the spindle 23 to rotate about its axis.

The cutting blade 21 is an extremely thin cutting grindstone having a substantially ring shape. In the first embodiment, the cutting blade 21 includes a ring-like cutting edge for cutting the workpiece 200, and a ring-like annular base supporting the cutting edge on its outer edge and being detachably mounted on the spindle 23. The cutting edge is made of abrasive grains such as diamond or cubic boron nitride (CBN) and a bonding member (binder) such as a metal or a resin and is formed to be a predetermined thickness. Note that the cutting blade 21 may be what is generally called a washer blade being made of a cutting edge only.

The spindle housing 22 is supported by the Z-axis moving unit to be freely movable in the Z-axis direction and is supported by the Y-axis moving unit through the Z-axis moving unit to be freely movable in the Y-axis direction. The spindle housing 22 accommodates portions other than a distal end portion of the spindle 23, the unillustrated spindle motor, and the like, therein, to support the spindle 23 to be rotatable about its axis.

The spindle 23 is mounted with the cutting blade 21 on the distal end portion thereof. The spindle 23 is rotated by the unillustrated spindle motor, and the distal end portion thereof protrudes from a distal end surface of the spindle housing 22. The distal end portion of the spindle 23 is formed to be gradually tapered toward the distal end thereof, and this distal end portion of the spindle 23 is mounted with the cutting blade 21. The spindle 23 of the cutting unit 20 and the axis of the cutting blade 21 are parallel to the Y-axis direction.

The imaging unit is fixed to the cutting unit 20 so as to integrally move with the cutting unit 20. The imaging unit includes an imaging element which captures an image of a region of the yet-to-be-cut workpiece 200 held by the holding unit 10, the region which is to be divided. The imaging element is, for example, a charge coupled device (CCD) imaging element or a complementary metal-oxide semiconductor (CMOS) imaging element. The imaging unit captures an image of the workpiece 200 held by the holding unit 10 and obtains an image used for performing alignment to carry out positioning between the workpiece 200 and the cutting blade 21, or the like, to output this obtained image to the controller 100.

In addition, the processing mechanism 2 includes an unillustrated X-axis direction position detecting unit which detects a position of the holding unit 10 in the X-axis direction, an unillustrated Y-axis direction position detecting unit which detects a position of the cutting unit 20 in the Y-axis direction, and a Z-axis direction position detecting unit which detects a position of the cutting unit 20 in the Z-axis direction. The X-axis direction position detecting unit may include a linear scale parallel to the X-axis direction and a reading head. Also, the Y-axis direction position detecting unit may include a linear scale parallel to the Y-axis direction, and a reading head. The Z-axis direction position detecting unit detects a position of the cutting unit 20 in the Z-axis direction according to a pulse of the motor. The X-axis direction position detecting unit outputs the position of the holding unit 10 in the X-axis direction to the controller 100. Also, the Y-axis direction position detecting unit outputs the position of the cutting unit 20 in the Y-axis direction to the controller 100. Also, the Z-axis direction position detecting unit outputs the position of the cutting unit 20 in the Z-axis direction to the controller 100. Note that, in the first embodiment, the respective positions of each constituent element of the processing apparatus 1 in the X-axis direction, the Y-axis direction, and the Z-axis direction are determined in reference to a predetermined reference position not illustrated.

In addition, the processing mechanism 2 includes a cassette elevator 40 where a cassette 41 for housing a plurality of workpieces 200 before and after cutting is placed and which causes the cassette 41 to move in the Z-axis direction. The cassette 41 is a housing container capable of housing the plurality of workpieces 200 to be spaced apart from each other in the Z-axis direction, and includes an inlet/outlet port 42 which allows the workpiece 200 to be loaded or unloaded. The cassette elevator 40 is disposed on a side in the Y-axis direction adjacent to the holding unit 10 positioned in the loading/unloading region, and the cassette 41 is placed so as to position the inlet/outlet port 42 on a side of the holding unit 10 positioned in the loading/unloading region.

In addition, the processing mechanism 2 includes a pair of guide rails 43. The pair of guide rails 43 are disposed above the holding unit 10 positioned in the loading/unloading region to support the workpiece 200. The pair of guide rails 43 are disposed to be spaced apart from each other at an interval in the X-axis direction. In addition, as depicted in FIG. 2, the pair of guide rails 43 are formed to be straight in parallel to the Y-axis direction and moved by the unillustrated moving unit in the X-axis direction such that the guide rails 43 are brought closer to each other or moved apart from each other. The pair of guide rails 43 each have a support wall which supports the workpiece 200 resulting from the placement of the annular frame 205, and a side wall erecting from each of edges of the support walls of the guide rails 43 on a side in which the edges are distant from each other.

An upper surface of the support wall is formed to be flat along the horizontal direction, and supports the annular frame 205 when the annular frame 205 of the workpiece 200 is placed thereon. The support wall supports the annular frame 205, thereby supporting the workpiece 200. The support walls of the pair of guide rails 43 are disposed on both ends of the annular frame 205 in the X-axis direction and support both ends of the annular frame 205 in the X-axis direction. As such, supporting the annular frame 205 supports the workpiece 200. The side wall is supported on the support wall, and when the guide rails 43 are brought closer to each other, the support walls of the guide rails 43 abut on respective outer edges of the annular frame 205. Thus, positioning of the annular frame 205, that is, positioning of the workpiece 200 in the X-axis direction can be carried out.

The first cleaning mechanism 3 cleans the workpiece 200 processed by cutting with the cutting unit 20. The first cleaning mechanism 3 is placed adjacent to the holding unit 10 positioned in the loading/unloading region on the other side in the Y-axis direction and disposed to be lined with the cassette 41 and the holding unit 10 positioned in the loading/unloading region in the Y-axis direction. As depicted in FIG. 2, the first cleaning mechanism 3 is provided in an opening hole 6 being opened in an upper surface of a mechanism main body of the processing mechanism 2. As depicted in FIG. 3, the first cleaning mechanism 3 includes a spinner table (depicted in FIG. 2) provided in the opening hole 6, a cleaning fluid nozzle 51, an unillustrated elevating unit which vertically moves up and down the spinner table 50 in the Z-axis direction, and an unillustrated rotational motor which causes the spinner table 50 to rotate about its axis parallel to the Z-axis direction.

The spinner table 50 holds the workpiece 200 processed by cutting with the cutting unit 20. The spinner table 50 has a holding surface 52 having a shape of a disc and parallel to the horizontal direction, and the holding surface 52 holds the workpiece 200 thereon and is formed of a porous ceramic material or the like. The holding surface 52 of the spinner table 50 is connected to an unillustrated vacuum suction source and sucked by the vacuum suction source, to thereby suck and hold the workpiece 200 placed on the holding surface 52. In the first embodiment, the spinner table 50 sucks and holds the back surface 204 side of the workpiece 200 through the adhesive tape 206.

The holding surface 52 of the spinner table 50 is moved up and down by the elevating unit in a range of a rising position at which the holding surface 52 is positioned at substantially the same height as the upper surface of the mechanism main body 5 to a lowering position at which the holding surface 52 is positioned closer to a bottom side of the opening hole 6 relative to the rising position. In addition, the spinner table 50 is rotated about its axis by the rotational motor at the lowering position. Moreover, the rotational motor generates a centrifugal force attributable to the rotation of the spinner table 50 about its axis, and the generated centrifugal force causes a plurality of clamps 53 provided around the spinner table 50 to cramp the annular frame 205.

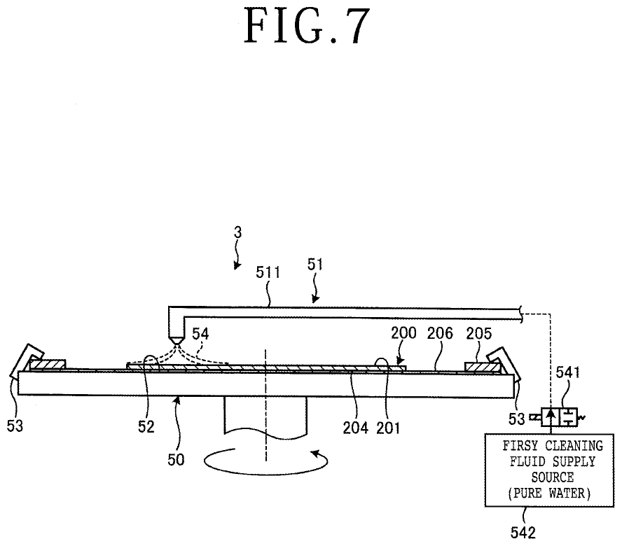

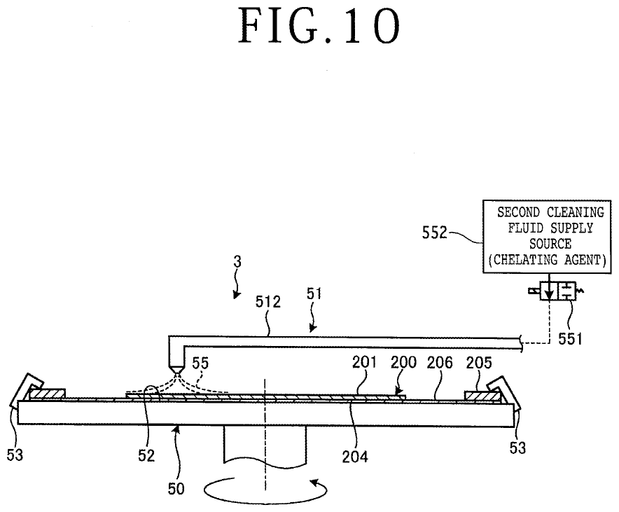

The cleaning fluid nozzle 51 cleans the workpiece 200 held by the spinner table 50 by supplying the workpiece 200 with cleaning fluids 54 and 55 (depicted in FIG. 7 and FIG. 10) containing water. The cleaning fluid nozzle 51 is arranged in the opening hole 6 and includes a first cleaning nozzle 511 and a second cleaning nozzle 512 which are parallel to each other. The first cleaning nozzle 511 and the second cleaning nozzle 512 are formed into a pipe-like shape extending along the horizontal direction and swingably disposed with each proximal end portion thereof as a center. Each of the first cleaning nozzle 511 and the second cleaning nozzle 512 is configured in such a manner that the proximal end portion thereof is rotated about its axis parallel to the Z-axis direction by the unillustrated motor. Owing to this rotation of the proximal end portion thereof as the center, each of the first cleaning nozzle 511 and the second cleaning nozzle 512 is configured such that the distal end portion thereof passes over an area above the workpiece 200 held by the spinner table 50 that is positioned at the lowering position.

The first cleaning nozzle 511 is connected with a first cleaning fluid supply source 542 through an on/off valve 541, supplying the front surface 201 of the workpiece 200 with the first cleaning fluid 54 (depicted in FIG. 7) from the first cleaning fluid supply source 542. When the first cleaning nozzle 511 swings with the proximal end portion thereof as the center, the first cleaning fluid 54 supplied form the first cleaning fluid supply source 542 is supplied onto the front surface 201 of the workpiece 200 held by the spinner table 50, from the distal end portion of the first cleaning nozzle 511. Note that, in the first embodiment, the first cleaning fluid 54 is made of pure water only or a combination of pure water and gas.

The second cleaning nozzle 512 is connected with a second cleaning fluid supply source 552 through an on/off valve 551 and supplies the front surface 201 of the workpiece 200 with a second cleaning fluid 55 (depicted in FIG. 10) from the second cleaning fluid supply source 552. When the second cleaning nozzle 512 swings with the proximal end portion thereof as the center, the second cleaning fluid 55 supplied from the second cleaning fluid supply source 552 is supplied onto the front surface 201 of the workpiece 200 held by the spinner table 50 from the distal end portion of the second cleaning nozzle 512. Note that, in the first embodiment, the second cleaning fluid 55 is made of a combination of pure water and a known chelating agent.

The second cleaning mechanism 4 cleans the front surface 201 of the workpiece 200 by polishing the front surface 201 of the workpiece 200 cleaned by the first cleaning mechanism 3. The second cleaning mechanism 4 is disposed adjacent to the first cleaning mechanism 3 on the other side of the Y-axis direction so as to be lined with the cassette 41, the holding unit 10 positioned in the loading/unloading region, and the first cleaning mechanism 3 in the Y-axis direction. As depicted in FIG. 4, the second cleaning mechanism 4 has a mechanism main body 60 attached to the mechanism main body 5 of the processing mechanism 2, a cleaning holding unit 61 installed in the mechanism main body 60, a polishing cleaning liquid supply unit 62, a polishing pad 63, an unillustrated elevating unit which moves up and down the polishing cleaning liquid supply unit 62 in the Z-axis direction, and an unillustrated rotational motor which causes the cleaning holding unit 61 to rotate about its axis parallel to the Z-axis direction.

The mechanism main body 60 has an opening hole 601 formed therein, the opening hole 601 being opened in an upper surface of the mechanism main body 60. The cleaning holding unit 61 holds the workpiece 200 cleaned by the first cleaning mechanism 3 and is installed in the opening hole 601 of the mechanism main body 60. The cleaning holding unit 61 has a holding surface 611 having a shape of a disc and parallel to the horizontal direction. The holding surface 611 for holding the workpiece 200 is made of a porous ceramic material or the like. The holding surface 611 of the cleaning holding unit 61 is connected to an unillustrated vacuum suction source and sucked by the vacuum suction source to suck and hold the workpiece 200 placed on the holding surface 611. In the first embodiment, the cleaning holding unit 61 sucks and holds the back surface 204 side of the workpiece 200 through the adhesive tape 206.

In the cleaning holding unit 61, the holding surface 611 is positioned at substantially the same height as an upper surface of the mechanism main body 60. Also, the cleaning holding unit 61 is rotated about its axis by the rotational motor. In addition, the rotational motor generates a centrifugal force attributable to rotation of the cleaning holding unit 61 about its axis, and the generated centrifugal force causes a plurality of clamps 612 provided around the cleaning holding unit 61 to cramp the annular frame 205.

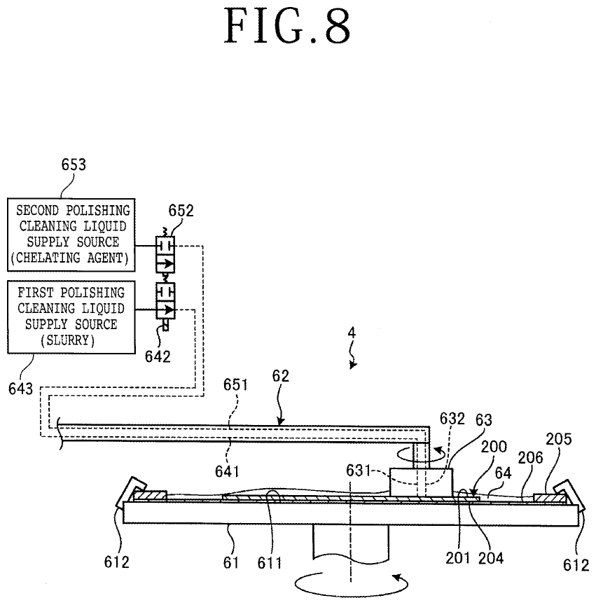

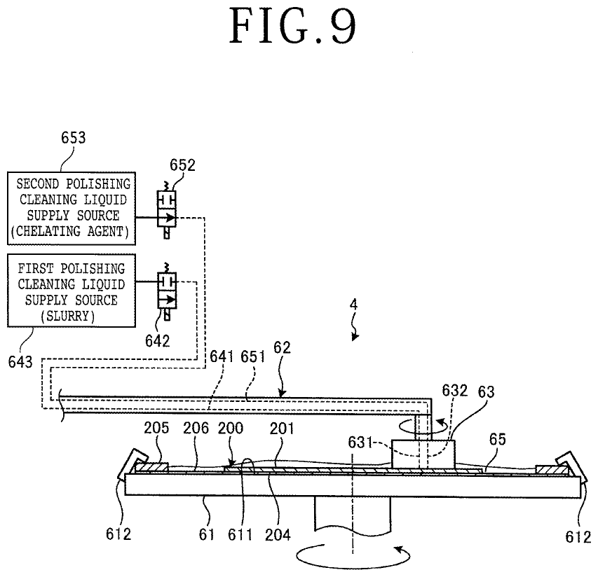

The polishing cleaning liquid supply unit 62 supplies the workpiece 200 held by the cleaning holding unit 61 with polishing cleaning liquids 64 and 65 (depicted in FIG. 8 and FIG. 9). The polishing cleaning liquid supply unit 62 is installed on the upper surface of the mechanism main body 60 and is formed in to a pipe-like shape extending along the horizontal direction, and swingably disposed with a proximal end portion thereof at a center. The polishing cleaning liquid supply unit 62 is rotated by an unillustrated motor such that the proximal end portion rotates about its axis parallel to the Z-axis direction. The polishing cleaning liquid supply unit 62 is rotated with the proximal end portion thereof as the center, causing the distal end portion thereof to pass over an area above the workpiece 200 held by the cleaning holding unit 61. In addition, the distal end portion of the polishing cleaning liquid supply unit 62 moves up and down in a range of the lowering position at which the distal end portion thereof comes closer to the front surface 201 of the workpiece 200 held by the cleaning holding unit 61 to the rising position at which the distal end portion thereof is positioned higher than the lowering position.

The polishing cleaning liquid supply unit 62 has a first cleaning liquid supply path 641 and a second cleaning liquid supply path 651 therein, which are separated from each other. In other words, the first cleaning liquid supply path 641 and a second cleaning liquid supply path 651 are not communicated with each other. The first cleaning liquid supply path 641 supplies the workpiece 200 held by the cleaning holding unit 61 with the first polishing cleaning liquid 64 and extends in a longitudinal direction of the polishing cleaning liquid supply unit 62.

The first cleaning liquid supply path 641 is connected with the first polishing cleaning liquid supply source 643 through an on/off valve 642, and the first polishing cleaning liquid 64 (depicted in FIG. 8) is supplied to the workpiece 200 from the first polishing cleaning liquid supply source 643 through the first cleaning liquid supply path 641. When the polishing cleaning liquid supply unit 62 is positioned at the lowering position by the elevating unit and swings with the proximal end portion thereof as the center, the first cleaning liquid supply path 641 allows the first polishing cleaning liquid 64 supplied from the first polishing cleaning liquid supply source 643 to be supplied onto the front surface 201 of the workpiece 200 held by the cleaning holding unit 61 from the distal end portion of the polishing cleaning liquid supply unit 62. Note that, in the first embodiment, the first polishing cleaning liquid 64 is a slurry made of an acid solution or an alkaline solution and abrasive grains. Note that the abrasive grains include diamond, CBN, or the like.

The second cleaning liquid supply path 651 allows the second polishing cleaning liquid 65 different from the first polishing cleaning liquid 64 to be supplied onto the workpiece 200 held by the cleaning holding unit 61. The second cleaning liquid supply path 651 extends along the longitudinal direction of the polishing cleaning liquid supply unit 62. The second cleaning liquid supply path 651 is connected with the second polishing cleaning liquid supply source 653 through on an on/off valve 652, and the second polishing cleaning liquid 65 (depicted in FIG. 9) is supplied onto the workpiece 200 from the second polishing cleaning liquid supply source 653 through the second cleaning liquid supply path 651. When the polishing cleaning liquid supply unit 62 is positioned at the lowering position by the elevating unit and swings with the proximal end portion thereof as the center, the second cleaning liquid supply path 651 allows the second polishing cleaning liquid 65 supplied from the second polishing cleaning liquid supply source 653 to be supplied onto the front surface 201 of the workpiece 200 held by the cleaning holding unit 61 from the distal end portion of the polishing cleaning liquid supply unit 62. Note that, in the first embodiment, the second polishing cleaning liquid 65 is made of pure water and a known chelating agent.

The polishing pad 63 abut on the front surface 201 of the workpiece 200 supplied with the polishing cleaning liquids 64 and 65 from the polishing cleaning liquid supply unit 62 to polish the front surface 201 of the workpiece 200, thereby cleaning the front surface 201 of the workpiece 200. The polishing pad 63 is formed into a shape of a disc, and in the first embodiment, is made of a material, such as a nonwoven fabric or urethane foam, allowing the polishing cleaning liquids 64 and 65 to pass therethrough. The polishing pad 63 is supported at the distal end portion of the polishing cleaning liquid supply unit 62 in such a manner as to be rotatable about the axis parallel to the Z-axis direction, and when the polishing cleaning liquid supply unit 62 is positioned at the lowering position, the polishing pad 63 can abut on the front surface 201 of the workpiece 200 held under suction on the holding surface 611 of the cleaning holding unit 61. The polishing pad 63 has supply paths 631 and 632 (depicted in FIG. 8) formed therein. The supply paths 631 and 632 communicate with the cleaning liquid supply paths 641 and 651, respectively, and lower surfaces of the supply paths 631 and 632 are opened to supply the polishing cleaning liquids 64 and 65 supplied from the cleaning liquid supply paths 641 and 651, respectively, onto the front surface 201 of the workpiece 200.

In addition, in the processing apparatus 1, an upper portion of each of the mechanism main bodies 5 and 60 is covered with an outer wall 7 depicted in FIG. 1 or the like, and the loading/unloading region and the processing region in the processing mechanism 2 are partitioned by a partition wall 8 depicted in FIG. 2. The partition wall 8 erects from the upper surface of each of the mechanism main bodies 5 and 60. In addition, the upper portion of the mechanism main body 60 of the second cleaning mechanism 4 is partitioned from the upper portion and the like of the mechanism main body 5 of the processing mechanism 2 by a partition wall 9 (depicted in FIG. 2). Note that the partition wall 9 is provided with an unillustrated opening through which a first transfer unit 71 of the transfer mechanism 70 can pass, and this opening is opened/closed by an opening/closing door not illustrated.

The transfer mechanism 70 transfers the workpiece 200 in a range from the interior of the cassette 41, the upper surfaces of the support walls of the pair of guide rails 43, the holding surface 11 of the holding unit 10, the holding surface 52 of the spinner table 50 of the first cleaning mechanism 3, to the holding surface 611 of the cleaning holding unit 61 of the second cleaning mechanism 4. The transfer mechanism 70 includes the first transfer unit 71 and the second transfer unit 72.

The first transfer unit 71 transfers the workpiece 200 from the interior of the cassette 41 onto the upper surfaces of the support walls of the pair of guide rails 43, transfers the workpiece 200 from the upper surfaces of the support walls of the pair of guide rails 43 to the holding surface 11 of the holding unit 10, and transfers the workpiece 200 from the holding surface 52 of the spinner table 50 of the first cleaning mechanism 3 to the holding surface 611 of the cleaning holding unit 61 of the second cleaning mechanism 4. In addition, the first transfer unit 71 transfers the workpiece 200 from the cleaning holding unit 61 of the second cleaning mechanism 4 to the upper surfaces of the support walls of the pair of guide rails 43, and transfers the workpiece 200 from the upper surfaces of the support walls of the pair of guide rails 43 into the cassette 41.

The first transfer unit 71 is moved by the moving unit 711 installed in the partition wall 8 in the Y-axis direction in a range from the upper surfaces of the support walls of the pair of guide rails 43, the holding surface 11 of the holding unit 10 positioned in the loading/unloading region, the holding surface 52 of the spinner table 50 of the first cleaning mechanism 3, to the holding surface 611 of the cleaning holding unit 61 of the second cleaning mechanism 4. In addition, the first transfer unit 71 is moved in the Z-axis direction by the elevating unit 712 being moved in the Y-axis direction by the moving unit 711.

The first transfer unit 71 includes a clamping portion 713, and a plurality of vacuum pads 714. The clamping portion 713 is provided at an end of the first transfer unit 71 closer to the cassette 41 in the Y-axis direction to clamp the annular frame 205. The plurality of vacuum pads 714 are provided on a lower surface side of the first transfer unit 71 to hold under suction the annular frame 205. The first transfer unit 71 causes the clamping portion 713 to clamp the annular frame 205 and is moved in the Y-axis direction by the moving unit 711, thereby loading/unloading the workpiece 200 to/from the cassette 41. The first transfer unit 71 holds under suction the annular frame 205 with the vacuum pad 714, is moved up and down by the elevating unit 712, and moved in the Y-axis direction by the moving unit 711, so that the workpiece 200 is transferred from the upper surfaces of the support walls of the pair of guide rails 43 to the holding surface 11 of the holding unit 10, passes through the opening provided in the partition wall 9, transferred from the holding surface 52 of the spinner table 50 of the first cleaning mechanism 3 to the holding surface 611 of the cleaning holding unit 61 of the second cleaning mechanism 4, and passes through the opening provided in the partition wall 9, thereby being transferred from the holding surface 611 of the cleaning holding unit 61 of the second cleaning mechanism 4 to the upper surfaces of the support walls of the pair of guide rails 43.

The second transfer unit 72 transfers the workpiece 200 from the holding surface 11 of the holding unit 10 to the holding surface 52 of the spinner table 50 of the first cleaning mechanism 3. The second transfer unit 72 is moved by the moving unit 721 installed in the partition wall 8 in the Y-axis direction in a range from the holding surface 11 of the holding unit 10 positioned in the loading/unloading region to the holding surface 52 of the spinner table 50 of the first cleaning mechanism 3. In addition, the second transfer unit 72 is moved up and down in the Z-axis direction by the elevating unit 722 being moved in the Y-axis direction by the moving unit 721.

The second transfer unit 72 includes a plurality of vacuum pads 724 which are provided on a lower surface side thereof and which hold under suction the annular frame 205. The second transfer unit 72 causes the vacuum pads 724 to hold under suction the annular frame 205 and is moved up and down by the elevating unit 722, and is moved in the Y-axis direction by the moving unit 721, thereby transferring the workpiece 200 from the holding surface 11 of the holding unit 10 to the holding surface 52 of the spinner table 50 of the first cleaning mechanism 3.

Note that the moving units 711 and 721 each includes a known ball screw provided in a rotatable manner about its axis, a known motor rotating the ball screw about its axis to move each of the elevating units 712 and 722 in the Y-axis direction, and a pair of known guide rails supporting each of the elevating units 712 and 722 in the Y-axis direction in a movable manner. Each of the elevating units 712 and 722 includes an air cylinder and the like to move up and down each of the transfer units 71 and 72.

The controller 100 controls the constituent elements of the processing apparatus 1, to thereby cause the processing apparatus 1 to carry out processing operation on the workpiece 200. Note that the controller 100 is a computer having a computing unit having a microprocessor such as a central processing unit (CPU), a storing unit having a memory such as a read only memory (ROM) or a random access memory (RAM), and an input/output interface unit. The computing unit of the controller 100 executes computing processing according to a computer program stored in the storing unit, to output a control signal for controlling the processing apparatus 1 to each of the constituent elements of the processing apparatus 1 through the input/output interface unit.

The controller 100 is connected to a display unit 101, an input unit 102, and a notification unit 103 (see FIG. 1). The display unit 101 includes a liquid crystal display which displays a state of processing operation and an image, and the like. The input unit 102 is used when the operator registers processing condition or the like. The input unit 102 includes at least one of a touch panel provided on the display unit 101 or an external input device such as a keyboard. The notification unit 103 issues a notification to the operator by outputting at least one of sound or light.

### (Processing Method)

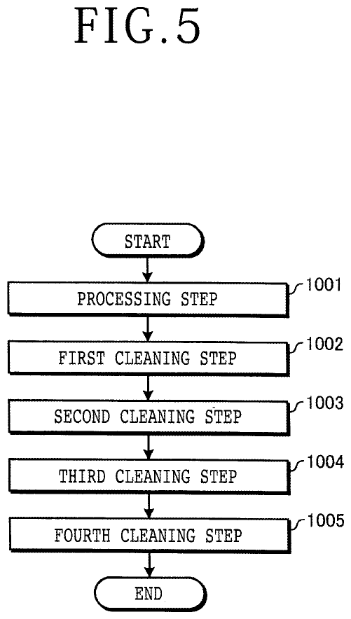

Next, a processing method according to the first embodiment of the present invention will be described with reference to the attached drawings. FIG. 5 is a flow chart indicating a flow of the processing method according to the first embodiment. The processing method according to the first embodiment is a method of processing the workpiece 200 by the processing apparatus 1 having the above-described configuration and includes the processing operation of the processing apparatus 1 having the above-described configuration.

When the operator registers the processing condition in the controller 100 and the cassette 41 housing an unprocessed workpiece 200 is placed on the upper surface of the cassette elevator 40 and the processing apparatus 1 then receives a start instruction of the processing operation from the operator, the processing apparatus 1 starts the processing operation, that is, the processing method according to the first embodiment. The processing method according to the first embodiment includes a processing step 1001, a first cleaning step 1002, a second cleaning step 1003, a third cleaning step 1004, and a fourth cleaning step 1005, as indicated in FIG. 5.

### (Processing Step)

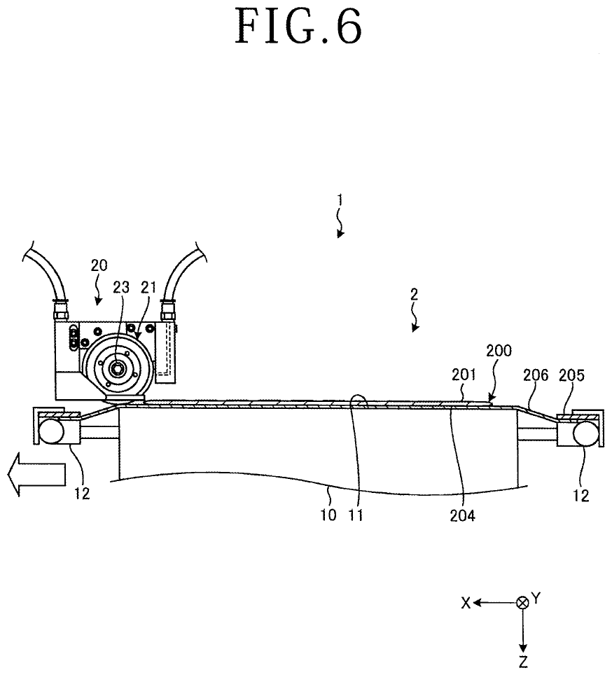

FIG. 6 is a schematic cross-sectional side view illustrating the processing step 1001 of the processing method indicated in FIG. 5. The processing step 1001 is a step of holding the workpiece 200 on the holding surface 11 of the holding unit 10 to perform cutting processing on the workpiece 200 held on the holding surface 11 of the holding unit 10. In the processing step 1001, the processing apparatus 1 rotates the spindle 23 about its axis, with the on/off valves 541, 551, 642, and 652 closed, and causes the holding unit 10 to be positioned in the loading/unloading region, causes the pair of guide rails 43 to be separated from each other, and causes the spinner table 50 and the polishing cleaning liquid supply unit 62 to be positioned at the rising position.

In the processing step 1001, the clamping portion 713 of the first transfer unit 71 clamps the annular frame 205 supporting the workpiece 200 in the cassette 41, and the first transfer unit 71 picks up the workpiece 200 from the interior of the cassette 41 to place the annular frame 205 on the upper surfaces of the support walls of the pair of guide rails 43. In the processing step 1001, the processing apparatus 1 brings the pair of guide rails 43 closer to each other, causes the workpiece 200 to be positioned in the X-axis direction, and causes the vacuum pad 714 of the first transfer unit 71 to hold under suction the annular frame 205 on the pair of guide rails 43.

In the processing step 1001, the processing apparatus 1 causes the first transfer unit 71 to be lowered to place the workpiece 200 supported by the annular frame 205 held under suction by the vacuum pad 714 onto the holding surface 11 of the holding unit 10, then stops the holding and suction of the vacuum pad 714, to thereby cause the first transfer unit 71 to be retracted from a position above the holding unit 10. In the processing step 1001, the processing apparatus 1 causes the holding unit 10 to hold under suction the back surface 204 side of the workpiece 200 through the adhesive tape 206 on the holding surface 11 of the holding unit 10 and causes the clamps 12 to clamp the annular frame 205.

In the processing step 1001, the X-axis moving unit causes the holding unit 10 to move toward the processing region, and the imaging unit captures an image of the workpiece 200. Thus, according to the image captured by the imaging unit, the processing apparatus 1 carries out alignment between the workpiece 200 and the cutting blade 21. In the processing step 1001, the processing apparatus 1 causes the holding unit 10 to move in the X-axis direction and the like, as illustrated in FIG. 6, and causes the workpiece 200 and the cutting unit 20 to move relative to each other along a predetermined one of the dividing lines 202, thereby causing the cutting blade 21 to cut the workpiece 200 along each of the dividing lines 202 to divide the workpiece 200 into individual devices 203. In the processing step 1001, when the processing apparatus 1 performs cutting processing on the workpiece 200 held on the holding surface 11 of the holding unit 10 along all of the dividing lines 202, the processing apparatus 1 causes the holding unit 10 to move to the loading/unloading region and then stops the holding unit 10 at the loading/unloading region. Then, the processing apparatus 1 stops holding and suction of the holding surface 11 of the holding unit 10.

In the processing step 1001, the processing apparatus 1 causes the vacuum pad 724 of the second transfer unit 72 to hold under suction the annular frame 205 supporting the workpiece 200 held on the holding surface 11 of the holding unit 10, to thereby transfer the workpiece 200 on the holding surface 11 of the holding unit 10 positioned in the loading/unloading region by the second transfer unit 72 to the spinner table 50 of the first cleaning mechanism 3. In the processing step 1001, the processing apparatus 1 causes the second transfer unit 72 to place the workpiece 200 on the holding surface 52 of the spinner table 50 and causes the second transfer unit 72 to be retracted from the first cleaning mechanism 3.

### (First Cleaning Step)

FIG. 7 is a schematic cross-sectional side view illustrating a first cleaning step 1002 of the processing method indicated in FIG. 5. The first cleaning step 1002 is a step of, after the processing step 1001 is carried out, holding the workpiece 200 on the holding surface 52 of the spinner table 50 and supplying a first cleaning fluid 54 containing water onto the front surface 201 of the workpiece 200 to clean the workpiece 200.

In the first cleaning step 1002, the processing apparatus 1 causes the spinner table 50 of the first cleaning mechanism 3 to hold under suction the back surface 204 side of the workpiece 200 on the holding surface 52 of the spinner table 50 through the adhesive tape 206 and then causes the spinner table 50 to be lowered to the lowering position. In the first cleaning step 1002, as illustrated in FIG. 7, the processing apparatus 1 opens the on/off valve 541, for a predetermined period of time, while rotating the spinner table 50 about its axis and swinging the proximal end portion of the cleaning nozzle 511, to supply the first cleaning fluid 54 from the first cleaning fluid supply source 542 to the front surface 201 of the workpiece 200 from the distal end portion of the first cleaning nozzle 511. As a result, a centrifugal force attributable to rotation of the spinner table 50 about its axis causes the clamps 53 to clamp the annular frame 205, and the first cleaning fluid 54 flows from the center of the front surface 201 of the workpiece 200 to the outer edge thereof, thereby removing foreign matter such as swarf adhered to the front surface 201 of the workpiece 200 to clean the front surface 201 of the workpiece 200.

In the first cleaning step 1002, after causing the spinner table 50 to rotate for a predetermined period of time while causing the cleaning nozzle 511 to swing and supplying the first cleaning fluid 54 to the front surface 201 of the workpiece 200, the processing apparatus 1 stops the rotation of the spinner table 50 and the swing motion of the cleaning nozzle 511, closes the on/off valve 541 to stop the supply of the first cleaning fluid 54. In the first cleaning step 1002, the processing apparatus 1 causes the distal end portion of the cleaning nozzle 511 to be retracted from a position above the spinner table 50, and causes the spinner table 50 to be moved upward so as to be positioned to the rising position.

In the first cleaning step 1002, the processing apparatus 1 causes the vacuum pad 714 of the first transfer unit 71 to hold under suction the annular frame 205 supporting the workpiece 200 on the holding surface 52 of the spinner table 50, and causes the first transfer unit 71 to transfer the workpiece 200 on the holding surface 52 of the spinner table 50 to the cleaning holding unit 61 of the second cleaning mechanism 4. In the first cleaning step 1002, the processing apparatus 1 causes the first transfer unit 71 to place the workpiece 200 on the holding surface 611 of the cleaning holding unit 61 and causes the first transfer unit 71 to be retracted from the second cleaning mechanism 4.

### (Second Cleaning Step)

FIG. 8 is a schematic cross-sectional side view illustrating the second cleaning step 1003 of the processing method indicated in FIG. 5. The second cleaning step 1003 is a step of, after the first cleaning step 1002 is carried out, causing the polishing pad 63 to abut on the front surface 201 of the workpiece 200 and supplying the first polishing cleaning liquid 64 to the workpiece 200, to polish the front surface 201 of the workpiece 200 with the polishing pad 63.

In the second cleaning step 1003, the processing apparatus 1 causes the cleaning holding unit 61 of the second cleaning mechanism 4 to hold under suction the back surface 204 side of the workpiece 200 on the holding surface 611 of the cleaning holding unit 61 through the adhesive tape 206 and then causes the polishing cleaning liquid supply unit 62 to be lowered to the lowering position. In the second cleaning step 1003, as illustrated in FIG. 8, the processing apparatus 1 opens the on/off valve 642, for a predetermined period of time, while supplying the first polishing cleaning liquid 64 from the first polishing cleaning liquid supply source 643 through the first cleaning liquid supply path 641 and the supply path 631 to the front surface 201 of the workpiece 200 and rotating the cleaning holding unit 61 about its axis, and swings the proximal end portion of the polishing cleaning liquid supply unit 62 to thereby causes the polishing pad 63 to abut on the front surface 201 of the workpiece 200.

Then, a centrifugal force attributable to the rotation of the cleaning holding unit 61 about its axis causes the clamps 612 to clamp the annular frame 205, and the first polishing cleaning liquid 64 flows from the center of the front surface 201 of the workpiece 200 toward the outer edge thereof, and the polishing pad 63 slides on the front surface 201 of the workpiece 200, the polishing pad 63 polishes the front surface 201 of the workpiece 200, that is, performs what is generally called chemical mechanical polishing (CMP), to clean the front surface 201 of the workpiece 200. In the second cleaning step 1003, after rotating the cleaning holding unit 61 and supplying the front surface 201 of the workpiece 200 with the first polishing cleaning liquid 64 through the first cleaning liquid supply path 641, for a predetermined period of time, the processing apparatus 1 closes the on/off valve 642 to stop the supply of the first polishing cleaning liquid 64.

### (Third Cleaning Step)

FIG. 9 is a schematic cross-sectional side view illustrating the third cleaning step 1004 of the processing method indicated in FIG. 5. The third cleaning step 1004 is a step of, after the second cleaning step 1003 is carried out, supplying the second polishing cleaning liquid 65 that is different from the first polishing cleaning liquid 64 to the workpiece 200 and polishing the front surface 201 of the workpiece 200 with the polishing pad 63 to clean the front surface 201 of the workpiece 200.

In the third cleaning step 1004, as illustrated in FIG. 9, the processing apparatus 1 opens the on/off valve 652, for a predetermined period of time, while supplying the second polishing cleaning liquid 65 from the second polishing cleaning liquid supply source 653 through the second cleaning liquid supply path 651 and the supply path 632 to the front surface 201 of the workpiece 200 and rotating the cleaning holding unit 61 about its axis, and swings the proximal end portion of the polishing cleaning liquid supply unit 62 to thereby cause the polishing pad 63 to abut on the front surface 201 of the workpiece 200. As a result, the second polishing cleaning liquid 65 flows from the center of the front surface 201 of the workpiece 200 to the outer edge thereof, and the polishing pad 63 slides on the front surface 201 of the workpiece 200, the polishing pad 63 polishes the front surface 201 of the workpiece 200, to thereby clean the front surface 201 of the workpiece 200.

After rotating the cleaning holding unit 61 and supplying the second polishing cleaning liquid 65 through the second cleaning liquid supply path 651 to the workpiece 200, for a predetermined period of time, the processing apparatus 1 stops the rotation of the cleaning holding unit 61 and the swing motion of the cleaning holding unit 61, and closes the on/off valve 652 to stop the supply of the second polishing cleaning liquid 65. In the third cleaning step 1004, the processing apparatus 1 causes the distal end portion of the polishing cleaning liquid supply unit 62 to be retracted from a position above the cleaning holding unit 61 and causes the cleaning holding unit 61 to be moved upward so as to be positioned to the rising position.

In the third cleaning step 1004, the processing apparatus 1 causes the vacuum pad 714 of the first transfer unit 71 to hold under suction the annular frame 205 supporting the workpiece 200 on the holding surface 611 of the cleaning holding unit 61, and causes the first transfer unit 71 to transfer the workpiece 200 on the holding surface 611 of the cleaning holding unit 61 to the holding surface 52 of the spinner table 50 of the first cleaning mechanism 3. In the third cleaning step 1004, the processing apparatus 1 causes the first transfer unit 71 to place the workpiece 200 on the holding surface 52 of the spinner table 50, and causes the first transfer unit 71 to be retracted from the first cleaning mechanism 3.

### (Fourth Cleaning Step)

FIG. 10 is a schematic cross-sectional side view illustrating the fourth cleaning step 1005 of the processing method indicated in FIG. 5. The fourth cleaning step 1005 is a step of, after the third cleaning step 1004 is carried out, holding the workpiece 200 on the holding surface 52 of the spinner table 50 and supplying the second cleaning fluid 55 that is different from the first cleaning fluid 54 containing water to the front surface 201 of the workpiece 200 to clean the workpiece 200.

In the fourth cleaning step 1005, the processing apparatus 1 causes the spinner table 50 of the first cleaning mechanism 3 to hold under suction the back surface 204 side of the workpiece 200 on the holding surface 52 of the spinner table 50 through the adhesive tape 206 and then causes the spinner table 50 to be lowered to the lowering position. In the fourth cleaning step 1005, as illustrated in FIG. 10, the processing apparatus 1 opens the on/off valve 551, for a predetermined period of time, while rotating the spinner table 50 about its axis and swinging the proximal end portion of the cleaning nozzle 512, to supply the second cleaning fluid 55 from the first cleaning fluid supply source 552 to the front surface 201 of the workpiece 200 from the distal end portion of the second cleaning nozzle 512. As a result, a centrifugal force attributable to rotation of the spinner table 50 about its axis causes the clamps 53 to clamp the annular frame 205, the second cleaning fluid 55 flow from the center of the front surface 201 of the workpiece 200 to the outer edge thereof, thereby removing foreign matter such as swarf attached to the front surface 201 of the workpiece 200 to clean the front surface 201 of the workpiece 200.

In the fourth cleaning step 1005, after causing the spinner table 50 to rotate for a predetermined period of time while causing the cleaning nozzle 512 to swing and supplying the second cleaning fluid 55 to the front surface 201 of the workpiece 200, the processing apparatus 1 stops the rotation of the spinner table 50 and the swing motion of the cleaning nozzle 512, and closes the on/off valve 551 to stop the supply of the second cleaning fluid 55. In the fourth cleaning step 1005, the processing apparatus 1 causes the distal end portion of the cleaning nozzle 512 to be retracted from a position above the spinner table 50, and causes the spinner table 50 to be moved upward so as to be positioned to the rising position.

In the fourth cleaning step 1005, the processing apparatus 1 causes the vacuum pad 714 of the first transfer unit 71 to hold under suction the annular frame 205 supporting the workpiece 200 on the holding surface 52 of the spinner table 50, and causes the first transfer unit 71 to transfer the workpiece 200 on the holding surface 52 of the spinner table 50 to the pair of guide rails 43 which are spaced from each other. In the fourth cleaning step 1005, the processing apparatus 1 causes the first transfer unit 71 to place the annular frame 205 supporting the workpiece 200 on the upper surfaces of the support walls of the pair of guide rails 43. In the fourth cleaning step 1005, the processing apparatus 1 brings the pair of guide rails 43 closer to each other to set the workpiece 200 at a desired position in the X-axis direction, and then, causes the clamping portion 713 of the first transfer unit 71 to clamp the annular frame 205 on the guide rails 43. Then, the processing apparatus 1 causes the first transfer unit 71 to transfer the workpiece 200 in the cassette 41 and to be retracted from the cassette 41. Thus, the processing method according to the first embodiment performs cutting processing on the workpiece 200 and then cleans the front surface 201 of the workpiece 200.

The processing apparatus 1 sequentially picks up the workpiece 200 from the cassette 41 one by one, performs cutting processing on the workpiece 200, cleans the workpiece 200, and then transfers the workpiece 200 into the cassette 41. When the processing apparatus 1 performs cutting processing on all of the workpieces 200 in the cassette 41 and cleans them, the processing operation is ended.

As described above, the processing apparatus 1 according to the first embodiment includes the first cleaning mechanism 3 which supplies the cleaning fluids 54 and 55 to the front surface 201 of the workpiece 200 to clean the front surface 201 of the workpiece 200, and the second cleaning mechanism 4 having the polishing cleaning liquid supply unit 62 which supplies the polishing cleaning liquids 64 and 65 to the front surface 201 of the workpiece 200 cleaned by the first cleaning mechanism 3, and the polishing pad 63 which polishes the front surface 201 of the workpiece 200 supplied with the polishing cleaning liquids 64 and 65 to clean the front surface 201 of the workpiece 200. Accordingly, the processing apparatus 1 according to the first embodiment causes the second cleaning mechanism 4 to polish and clean the front surface 201 of the workpiece 200, after the first cleaning mechanism 3 cleans the front surface 201 of the workpiece 200.

Hence, the processing apparatus 1 according to the first embodiment can further reduce adherence of foreign matter to the front surface 201 of the workpiece 200 processed by dicing, than before.

In addition, since, after the front surface 201 of the workpiece 200 is cleaned in the first cleaning step 1002, the front surface 201 of the workpiece 200 is polished and cleaned in the second cleaning step 1003, the processing method according to the first embodiment can further reduce adherence of foreign matter to the front surface 201 of the workpiece 200 processed by dicing, than before.

Moreover, the second polishing cleaning liquid 65 containing the chelating agent is supplied to the front surface 201 of the workpiece 200 in the third cleaning step 1004 to polish and clean the front surface 201 of the workpiece 200, so that the processing method according to the first embodiment can prevent corrosion of the electrodes and the like of the devices 203 of the workpiece 200.

### Modification Example

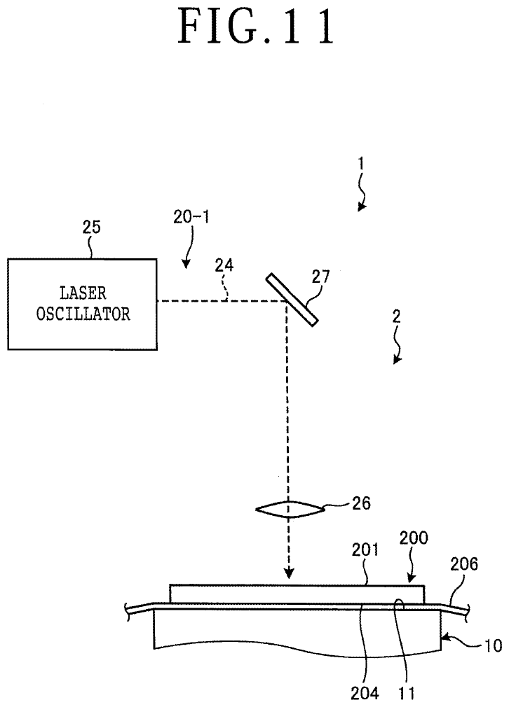

A processing apparatus and a processing method according to a modification example of the first embodiment of the present invention will be described with reference to the attached drawing. FIG. 11 is a schematic view illustrating a configuration of a laser processing unit 20-1 as a processing unit of the processing apparatus 1 according to the modification example of the first embodiment.

A configuration of the processing apparatus 1 of the modification example of the first embodiment is the same as that of the first embodiment except that the processing mechanism 2 has the laser processing unit 20-1 as the processing unit, as illustrated in FIG. 11. The laser processing unit 20-1 includes a laser oscillator 25 that generates a laser beam 24, a focusing lens 26 as a beam condenser that focuses the laser beam 24 generated in the laser oscillator 25 to the workpiece 200, a reflection mirror 27 that reflects the laser beam 24 generated in the laser oscillator 25 toward the focusing lens 26. The laser beam 24 has such a wavelength as to be absorbed in the workpiece 200. The laser processing unit 20-1 of the processing mechanism 2 of the processing apparatus 1 according to the modification example applies the laser beam 24 to the workpiece 200, performing laser processing (also referred to as ablation processing, and corresponding to processing) on the workpiece 200.

Also, in the processing method according to the modification example, in the processing step 1001, the processing apparatus 1 causes the holding unit 10 to hold the workpiece 200 on the holding surface 11 thereof, to perform laser processing on the workpiece 200 held on the holding surface 11 of the holding unit 10.

As in the first embodiment, since, after the first cleaning mechanism 3 cleans the front surface 201 of the workpiece 200 in the first cleaning step 1002, the second cleaning mechanism 4 polishes and cleans the front surface 201 of the workpiece 200 in the second cleaning step 1003, the processing apparatus 1 and the processing method according to the modification example produces the effect capable of further reducing adherence of foreign matter to the front surface 201 of the workpiece 200 processed by dicing, than before.

Note that the present invention is not limited to the embodiment described above, and various modifications can be made without departing from the gist of the present invention. Moreover, in the above-described embodiment and the like, the processing method includes the first cleaning step 1002, the second cleaning step 1003, the third cleaning step 1004, and the fourth cleaning step 1005. However, it is sufficient if the processing method may include at least the first cleaning step 1002 and the second cleaning step 1003. Further, in the processing method, in order to prevent the first polishing cleaning liquid 64 as the slurry in the second cleaning step 1003 from corrosion of the electrodes of the devices 203, in the third cleaning step 1004 or the fourth cleaning step 1005, it is preferable to clean the front surface 201 of the workpiece 200 with the second polishing cleaning liquid 65 or the second cleaning fluid 55 which both contain the chelating agent. Alternatively, either the third cleaning step 1004 or the fourth cleaning step 1005 may be carried out. Further, as the fourth cleaning step 1005, in addition to cleaning with the second cleaning fluid 55 containing the chelating agent, it may be preferable to perform ultrasonic cleaning of applying ultrasonic vibration to pure water or dry ice cleaning.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A processing apparatus which processes a workpiece, comprising:
a processing mechanism having a holding unit which holds the workpiece, and a processing unit which processes the workpiece held by the holding unit;
a first cleaning mechanism having a spinner table on which the workpiece processed by the processing unit is held, and a cleaning fluid nozzle which supplies a cleaning fluid containing water to clean the workpiece held on the spinner table; and
a second cleaning mechanism including a cleaning holding unit which holds the workpiece cleaned by the first cleaning mechanism, a polishing cleaning liquid supply unit which supplies a polishing cleaning liquid to the workpiece held by the cleaning holding unit, and a polishing pad which abuts on the workpiece supplied with the polishing cleaning liquid to polish the workpiece, thereby cleaning the workpiece.

2. The processing apparatus according to claim 1, wherein
the processing mechanism includes at least any one of a cutting unit having a spindle on which a cutting blade is mounted, or a laser processing unit having a laser oscillator which generates a laser beam and a beam condenser which focuses the laser beam generated in the laser oscillator to the workpiece.

3. The processing apparatus according to claim 1, wherein
the polishing cleaning liquid supply unit of the second cleaning mechanism has a first cleaning liquid supply path through which a first polishing cleaning liquid is supplied to the workpiece held by the cleaning holding unit, and a second polishing cleaning liquid supply path through which a second polishing cleaning liquid different from the first polishing cleaning liquid is supplied to the workpiece held by the cleaning holding unit.

4. A processing method for a workpiece, comprising:
a processing step of holding a workpiece by a holding unit, and processing the workpiece held by the holding unit;
a first cleaning step of, after the processing step is carried out, holding the workpiece by a spinner table, and supplying a cleaning fluid containing water to the workpiece to clean the workpiece; and
a second cleaning step of, after the first cleaning step is carried out, supplying a polishing cleaning liquid to the workpiece and causing the polishing pad to abut on the workpiece and polish the workpiece to clean the workpiece.

5. The processing method according to claim 4, further comprising:
a third cleaning step of, after the second cleaning step is carried out, supplying a second polishing cleaning liquid different from the polishing cleaning liquid to the workpiece and causing the polishing pad to polish the workpiece to clean the workpiece.
